(19) United States
(12) Patent Application Publication
(10) Pub. No.: US 2025/0237729 A1
(43) Pub. Date: Jul. 24, 2025

(54) OVER AND/OR UNDER VOLTAGE TESTING

(71) Applicant: ELESTA GmbH, Bad Ragaz (CH)

(72) Inventor: Raphael Möhr, Maienfeld (CH)

(21) Appl. No.: 19/024,404

(22) Filed: Jan. 16, 2025

(30) Foreign Application Priority Data
Jan. 23, 2024 (CH) CH000079/2024

(51) Int. Cl. G01R 35/00

(52) U.S. Cl. CPC G01R 35/007

(57) ABSTRACT

A method for checking the functionality of the voltage monitoring of a circuit is presented and described. The method includes a computing unit sending a test signal to a voltage source, which causes a change in the voltage of the voltage source. A comparison unit compares the voltage at the output of the voltage source with a reference voltage and sends a shutdown signal to a switch if the voltage at the output of the voltage source is outside a predetermined tolerance range. The switch interrupts the flow of current when it receives a shutdown signal, causing the voltage after the switch to drop.

According to the invention, the computing unit measures the voltage after the switch and draws conclusions about the functionality of the voltage monitor based on this voltage.

### TECHNICAL FIELD OF THE INVENTION

The invention relates to a method for checking the functionality of the voltage monitoring of a circuit according to claim 1 and a circuit according to the generic term of claim 11.

### BACKGROUND TO THE INVENTION

A typical field of application for methods and circuits in the sense of the invention is the automation industry. Automation technology is a branch of plant engineering and engineering science that deals with the automation of technical processes in complex machines and plants. Electrical circuits within the meaning of the invention relate in particular to circuits for monitoring the system voltage and for interrupting the transmission of the voltage if it is outside defined limits. Such circuits for monitoring and interrupting the voltage (often also referred to simply as “voltage monitoring”) are used, for example, where overvoltage leads to a system state that is critical to safety and the currentless state represents a safe system state. For example, such electrical circuits are responsible, among other things, for monitoring the system voltage in different operating modes. The consequences of a malfunction of such a circuit can have major effects, since the monitoring and interruption of the system voltage (“voltage monitoring”) would no longer be guaranteed. Due to the wide range of functions of the circuit, ensuring that the circuit functions reliably is of great importance in order to avoid dangerous situations. Since ensuring error-free operation is often not trivial or cannot be fully achieved, the usual approach is to use redundant circuitry. Redundancy, in which redundant circuits for monitoring and interrupting the voltage are arranged in series, for example, increases the robustness of the “monitoring and interruption” function. The disadvantage of such an arrangement, however, is often that the circuits are not tested during operation. For example, the reliable function or operability of the voltage monitoring of a circuit is ensured by redundancy with two elements arranged in series. These elements may include a switch that has an integrated shutdown mechanism that is activated when a voltage outside the permitted system voltage range occurs. The advantage of this is that these voltage monitoring elements are redundant in the circuit and, if one voltage monitoring element fails, a second element can take over the task. However, once it has been put into operation, the voltage monitor is not continuously checked for functionality during operation. This arrangement is therefore prone to a malfunction that occurs gradually or via a common-cause failure in both voltage monitors. Due to the lack of control of the voltage monitoring, i.e., a lack of functional control of the circuit for monitoring and interrupting the voltage, there is no information about the functionality of the circuit at any given time. Furthermore, the production and installation of two elements (two circuits) for voltage monitoring involves almost double the material costs and installation volume compared to a single element (a single circuit).

### TASK

The purpose of the present invention is to demonstrate a method for checking the functionality of a voltage monitor (circuit for monitoring the system voltage with integrated voltage interruption), which enables a cost-effective and space-saving implementation of a circuit. Furthermore, a circuit for voltage monitoring that is as cost-effective and space-saving as possible is to be demonstrated.

### DESCRIPTION

The problem is solved using a method with the features of claim 1.

The invention relates to a method for checking the functionality of the voltage monitoring of a circuit. The method according to the invention and the circuit according to the invention described below for checking the functionality of a voltage monitor are used in particular in the automation industry.

In a first step, a computing unit sends a test signal to a voltage source, which causes a change in the voltage of the voltage source. A comparison unit compares the voltage at the output of the power source with a reference voltage and sends a shutdown signal to a switch (which is provided to interrupt the current flow as part of the voltage monitoring) if the voltage at the output of the power source is outside a tolerance range. The switch breaks the flow of current when it receives a shutdown signal, causing the voltage to drop downstream of the switch. The method according to the invention is characterized by the fact that the computing unit measures the voltage after the switch and, on the basis of this voltage, draws conclusions about the functionality of the voltage monitor.

The method according to the invention makes it possible to check the functionality of a voltage monitor by using a test signal from a computing unit. The test signal is used to generate a voltage that is outside the tolerance range of the operating voltage and causes the switch to interrupt. The interruption of the switch is triggered by a shutdown signal from a comparison unit, which is sent when the comparison unit determines that the voltage at the output of the voltage source is outside the tolerance range. This is to check whether the switch-off mechanism is working and whether voltage monitoring is guaranteed in the circuit. This method can be used to ensure the functionality of a voltage monitor in a circuit, wherein the circuit does not have to have any redundant elements for this purpose. By avoiding redundancy, i.e., by using the elements in single versions in the circuit, the circuit becomes both cost-effective to manufacture and space-saving in size.

Preferably, the test signal causes an increase or decrease in the voltage of the voltage source. The test signal can increase or decrease the voltage of the voltage source, thereby changing the voltage at the output of the voltage source accordingly. The system voltage has a tolerance range with an upper and lower limit. For this reason, the voltage monitor can be checked for functionality by reducing or increasing the voltage.

The computing unit advantageously transmits a test signal at regular time intervals. The functionality of the voltage monitor is checked by sending a test signal from the computing unit. The computing unit can be set to send a test signal to the voltage source at specific, predefined time intervals. This allows for a regular check of the functionality of the voltage monitor.

The circuit's operating voltage should preferably be between 4.5 and 5.5 V, and more preferably between 4.85 and 5.15 V, wherein the operating voltage range defines the range in which the system is guaranteed to function. This also determines the range of application of the circuit.

The voltage changed by the test signal is preferably outside the working voltage range and within a defined voltage range in which no overloading of the system occurs. The task of the test pulse is to bring the voltage outside the operating voltage range. Preferably, the voltage is within a defined voltage range so that the elements of the circuit are not exposed to such high voltage differences that they can suffer damage, which in turn could reduce the lifespan of the circuit. A voltage of 6 V can be provided as the upper limit for this voltage range.

In a further embodiment, the operating voltage range of the circuit is between 3.0 and 3.6 V, preferably between 3.2 and 3.4 V, wherein the operating voltage range defines the range in which the system is guaranteed to function. Here, too, the voltage changed by the test signal is preferably outside the operating voltage range and within a defined voltage range, wherein a voltage of 4 V can be provided as the upper limit for this voltage range.

Preferably, the power supply reduces a supply voltage as input voltage to the system voltage. In this case, the voltage source serves as a voltage converter. The supply voltage can be any voltage that is provided. As long as the voltage source reduces the voltage to the system voltage, the circuit is functional.

In another preferred embodiment, the supply voltage is between 10 V and 50 V, preferably between 18 V and 30 V. Thus, the supply voltage covers the range used in automation devices. Preferably, the operation of the circuit during the transmission of a test signal and the possible switching off of the switch by a second voltage source is maintained. The second voltage source ensures that the voltage at the output of the circuit does not drop to zero and that the circuit thus continues to operate.

The second voltage source preferably includes capacitors. Capacitors can serve as a voltage source when checking the functionality of the voltage monitor in the circuit, as they can store electrical energy. During normal operation, the capacitors are charged and can provide power to the circuit by discharging when needed.

Another aspect of the invention relates to a circuit for checking the functionality of a voltage monitor. The circuit includes a voltage source that provides an adjustable output voltage, and a switch to interrupt the flow of current. Furthermore, the circuit includes a comparison unit that compares the voltage at the output of the voltage source with a reference voltage and can send a switch-off signal to the switch based on the result of the comparison. A computing unit measures the voltage at the output of the switch. The computing unit is intended to send a test signal to the voltage source in order to change the voltage of the voltage source and to check the functionality of the voltage monitor with the voltage at the output of the switch.

Preferably, the voltage at the output of the voltage source has a tolerance range and the comparison unit sends a shutdown signal to the switch if the measured voltage at the output of the voltage source is outside this tolerance range.

A second voltage source, in particular capacitors, is advantageously provided, which supplies current to the output of the circuit when the current flow through the switch is interrupted and ensures the continued functioning of the circuit.

A protective device is preferably arranged between the second voltage source and the switch in such a way that the current can never flow from the second voltage source to the switch and the measurement of the computing unit by the second voltage source is not influenced. Preferably, the protective device against feedback is formed by a semiconductor circuit, in particular a diode. Optional features mentioned can be realized in any combination, as long as they are not mutually exclusive. In particular, where preferred ranges are given, further preferred ranges result from combinations of the minima and maxima mentioned in the ranges.

Further advantages and features of the invention result from the following description of exemplary embodiments of the invention with reference to schematic illustrations.

### BRIEF DESCRIPTION OF THE FIGURES

It shows in a non-scale, schematic representation:

FIG. 1: a circuit diagram of a circuit according to the invention;

FIG. 2: a graph showing the voltage at four points in the circuit over time when a test signal is sent;

### DETAILED DESCRIPTION OF THE FIGURES

The same reference numbers below stand for the same or functionally identical elements in different figures. An additional apostrophe can serve to distinguish similar or functionally equivalent or functionally similar elements in a further embodiment.

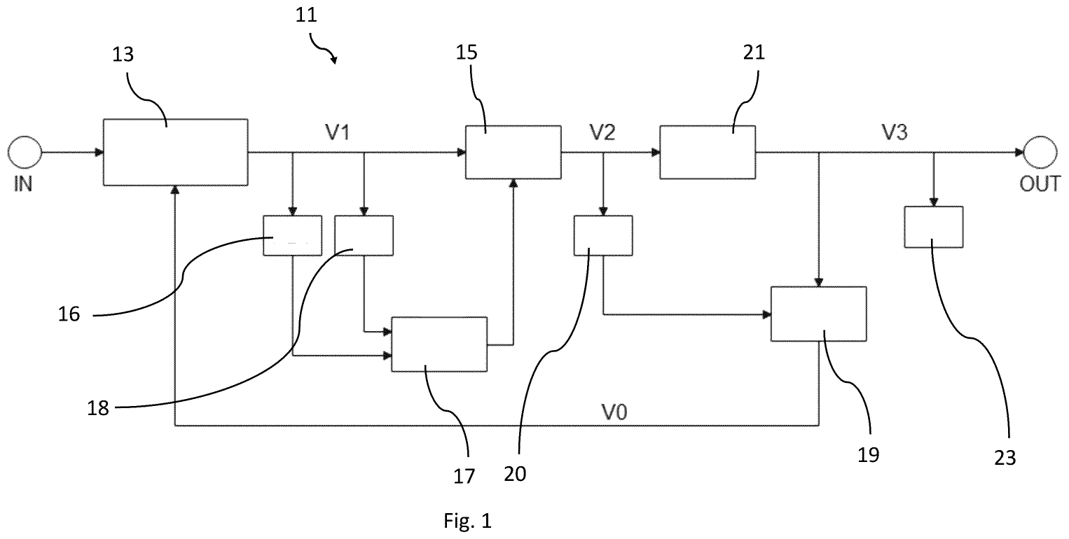

FIG. 1 shows a circuit diagram of a circuit 11 according to the invention with a switch-off function in the event of over-or undervoltage. The supply voltage is applied to the variable voltage source 13. The voltage source 13 converts the supply voltage into a lower system voltage, which is monitored by the subsequent circuit 11 with a switch 15. The power supply 13 has the ability to vary the system voltage. The system voltage can be changed at pre-set intervals or by external input. A comparison unit 17 is installed between the voltage source 13 and the switch 15. The comparison unit 17 compares the actual voltage at the output of the voltage source, which is forwarded to the comparison unit 17 by means of a first voltage feedback unit 16, and compares it to a reference voltage from a reference voltage source 18. If the deviation is greater than a permitted tolerance, an overvoltage or undervoltage is present and the comparison unit 17 sends a shutdown signal to the switch 15. The switch 15 is followed in the circuit 11 by a computing unit 19 and a diode 21. Diode 21 is designed to transmit the current from switch 15 to the output of the circuit on one side. The computing unit 19 receives the voltage at the outlet of the switch by means of a second voltage feedback unit 20. The voltage at the switch outlet allows the computing unit 19 to determine whether the voltage monitoring of the circuit 11 is working. At the same time, the computing unit 19 is connected to the voltage source 13. The computing unit 19 initiates the test for voltage monitoring and sends a test signal to the voltage source 13, which changes the voltage of the voltage source. If the voltage is above or below the tolerance range of the system voltage, the comparison unit 17 generates a switch-off signal for the switch 15, whereupon the switch 15 interrupts the current flow. The voltage across the switch drops rapidly because diode 21 blocks the access of current from the circuit output to the switch. After diode 21, another voltage source 23 is attached in the form of capacitors. The current in this second voltage source 23 begins to flow when the voltage before and thus also after diode 21 is reduced. The second voltage source 23 thus ensures a stable voltage state after diode 21 and at the circuit output, which generally means that the continued function of circuit 11 is not interrupted when a test is carried out. Due to the property of the diode 21 of only allowing current to flow in one direction, the voltage at the switch's output, which is measured by the computing unit 19, remains unaffected by the second voltage source 23.

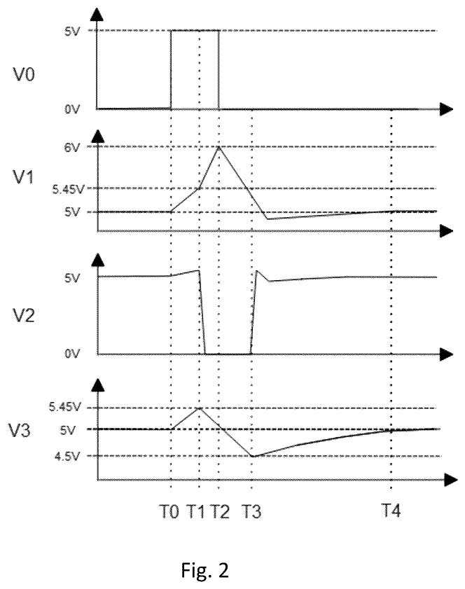

FIG. 2 shows the voltages at four different points in the circuit (V0, V1, V2, and V3) over time, wherein the diagrams are displayed on top of each other in such a way that the horizontal axis forms the same time axis in all diagrams. The first diagram shows the voltage over time at the connection between the computing unit 19 and the first voltage source 13, which is detected by the first voltage feedback unit 16. The second diagram shows the voltage curve between the first voltage source 13 and the switch 15. The voltage at the output of switch 15, which is detected by the second voltage feedback unit 20, is shown in the third diagram. The fourth diagram shows the voltage curve at the output of circuit 11. At time t0, the test for voltage monitoring is triggered by the computing unit 19 by sending a signal to the first voltage source 13. In this case, the signal causes an increase in the voltage at the output of voltage source 13. This voltage is continuously monitored and controlled by the comparison unit 17. As a result of the voltage increase at the output of the voltage source, the voltage after the switch also increases. At time t1, the voltage at the output of the power supply reaches a value that is no longer within the tolerance range of the operating voltage and is detected by the comparison unit 17. The comparison unit 17 then sends a shutdown signal to the switch 15, whereupon the switch 15 interrupts the current flow. Within a very short time, the voltage after the switch drops to zero. The computing unit 19, which triggered the test and caused the voltage increase, measures the dropped voltage at the output of the switch and recognizes that the test was successful. After the computing unit 19 has detected the expected voltage reduction, the computing unit 17 stops sending the test signal to the first voltage source 13 at time t2. When the test signal is no longer present, the voltage at the voltage source 13 is reduced again. The voltage drop across the switch, which has continued to increase until time t2 despite the interrupted switch, is reduced after the test signal has been removed. If the voltage before the switch, which is continuously monitored by the comparison unit 17, falls below a certain value and thus returns to within the tolerance range of the operating voltage, the comparison unit 17 sends the signal to switch 15 to cancel the interruption of the current flow at time t3. Since the voltage before the switch is always at an elevated level, the voltage at the output of the switch also rises rapidly after the interruption has been removed, so that within a short time after t3 the voltage at the output of the switch is at a similar level to that before the interruption. In contrast to the state before the interruption, the voltage at the input and thus also at the output of the switch decreases and approximately approaches the system voltage. The voltage at the output of the circuit, the progression of which is shown in the fourth diagram, also rises after the test signal is sent (t0) until the switch is interrupted (t1). In contrast to the voltage after the switch, the voltage at the output of the circuit after t1 does not suddenly drop to zero, but decreases slowly. The reason for the slow decrease in voltage is a second voltage source 23 in the form of capacitors, which is located at the output of the circuit and ensures a certain current supply at the output of the circuit when the current flow through the switch 15 is interrupted. The current of the second voltage source 23 cannot influence the voltage at the output of the switch due to the diode between the output of the circuit and the switch. The capacitors discharge until time t3, after which the current can flow again through the switch. The voltage at the output of circuit 11 takes comparatively longest to reach approximately the system voltage, because the capacitors are charged at the same time and part of the current is used for this.

While the invention has been described above with reference to specific embodiments, it is apparent that changes, modifications, variations, and combinations can be made without departing from the spirit of the invention.

### LIST OF REFERENCE SYMBOLS

11 Circuit
13 First voltage source
15 Switch
16 First voltage feedback unit
17 Comparison unit
18 Reference voltage source
19 Computing unit
20 Second voltage feedback unit
21 Diode
23 Second voltage source

1.-15. (canceled)

16. Method for checking the functionality of the voltage monitoring of a circuit, comprising the following steps:
a computing unit sends a test signal to a first voltage source, which causes a change in the voltage of the voltage source;
a comparison unit compares the voltage at the output of the voltage source with a reference voltage and sends a shutdown signal to a switch if the voltage at the output of the voltage source is outside a tolerance range,
the switch interrupts the flow of current upon receipt of a shutdown signal, causing the voltage after the switch to drop,
wherein
the computing unit measures the voltage after the switch and, on the basis of this voltage, draws conclusions about the functionality of the voltage monitor.

17. A method according to claim 16, wherein the test signal causes an increase or decrease in the voltage of the voltage source.

18. A method according to claim 16, wherein the computing unit transmits a test signal at regular time intervals.

19. A method according to claim 16, wherein the operating voltage range of the circuit is
between 4.5 and 5.5 V, or
between 3.0 and 3.6 V,
wherein the working voltage range defines the range in which the system's function is guaranteed.

20. A method according to claim 16, wherein the voltage changed by the test signal is outside the operating voltage range and within a defined voltage range in which no overloading of the system takes place.

21. A method according to claim 16, wherein the maximum voltage for ensuring the function of the voltage monitor is between approximately 5.5 and 6 V or between 3.6 and 4 V.

22. A method according to claim 16, wherein the voltage source reduces a supply voltage as input voltage to the system voltage.

23. A method according to claim 16, wherein the supply voltage is between 10 V and 50 V.

24. A method according to claim 16, wherein the operation of the circuit is maintained during the transmission of a test signal and the possible switching off of the switch by means of a second voltage source.

25. A method according to claim 16, wherein the second voltage source comprises capacitors.

26. Circuit for checking the functionality of a voltage monitor, comprising:
a voltage source that provides an adjustable output voltage,
a switch for interrupting the flow of current,
a comparison unit that compares the voltage at the output of the voltage source with a reference voltage and, based on the comparison result, can send a switch-off signal to the switch,
a computing unit which measures the voltage at the output of the switch, wherein
the computing unit is provided to send a test signal to the voltage source in order to change the voltage of the voltage source and to check the operability of the voltage monitoring with the voltage at the output of the switch.

27. A circuit according to claim 26, wherein the voltage at the output of the voltage source has a tolerance range and the comparison unit sends a switch-off signal to the switch if the measured voltage at the output of the voltage source is outside this tolerance range.

28. A circuit according to claim 26, wherein a second voltage source, in particular capacitors, is provided which, when the current flow through the switch is interrupted, supplies current to the output of the circuit and ensures the continued functioning of the circuit.

29. A circuit according to claim 26, wherein a protection device against feedback is arranged between the second voltage source and the switch in such a way that the current can never flow from the second voltage source to the switch and the measurement of the computing unit is not influenced by the second voltage source.

30. A circuit according to claim 26, wherein the protective device against feedback is formed by a semiconductor circuit, in particular a diode.
